(19) United States
(12) Patent Application Publication
(10) Pub. No.: US 2026/0230070 A1
(43) Pub. Date: Aug. 6, 2026

(54) TEMPERATURE-COMPENSATED OVER-CURRENT DETECTION SYSTEM

(71) Applicant: Mitsubishi Electric Corporation, Tokyo (JP)

(72) Inventors: Nicolas DEGRENNE, Rennes (FR); Vincent QUEMENER, Rennes (FR)

(73) Assignee: Mitsubishi Electric Corporation, Tokyo (JP)

(21) Appl. No.: 19/147,773

(22) PCT Filed: Mar. 15, 2024
(86) PCT No.: PCT/JP2024/080030

§ 371 Date: Jul. 14, 2025

(30) Foreign Application Priority Data
May 25, 2023 (EP) 23305830.4

(51) Int. Cl. H03K 17/082; H03K 17/08; H03K 17/14

(52) U.S. Cl. CPC H03K 17/0822; H03K 17/145; H03K 2017/0806; H03K 2217/0027

(57) ABSTRACT

A semiconductor switch includes a detection circuit comprising a compensation circuit connected between a current mirror output and a low voltage level of a driver voltage source, and connected to a first adder input having a second adder input receiving an offset V_{ofst} to provide a mirror voltage Vs mirroring the current Ic. The compensation circuit includes a current source configured connected to a temperature sensitive element in which a reference current i_{R} flows through the temperature sensitive element to provide a reference voltage Ve, a comparator, comparing the reference voltage Ve or an amplified reference voltage βVd and the mirror voltage and the compensation circuit is configured to provide at an output of the comparator a detection signal Ocd changing its state when the mirror voltage exceeds the reference voltage Ve or the amplified reference voltage βVd.

### TECHNICAL FIELD

This disclosure pertains to the field of the protection of power semiconductor switches such as IGBTs or MOSFETs against over currents and damages caused by such over currents. Priority is claimed on European Patent Application No. EP23305830.4, filed May 25, 2023, the content of which is incorporated herein by reference.

### BACKGROUND ART

It is known to provide a measurement of the collector-emitter or drain-source current of a power semiconductor switch in order to detect occurrence of an over current.

Monitoring the current through a power semiconductor switch such as IGBT or MOSFET is important to protect it from over-current or short-circuit (e.g. shoot-through) current. Several means to measure this current can be found in the literature. Monolithic current mirrors built-in the power dies or chips can provide a scaled value of the collector (or drain) current in a compact and reliable way and are implemented in several commercial products. FIG. 1 shows an example of current measurement device for an IGBT 10 having a current mirror output 12 which gives a current signal proportional to the output current of the IGBT, e.g. 1/100 of the output current of the IGBT. The current measurement device comprises a sense resistor Rs, a low pass filter 21 and a comparator 22 having a reference voltage V_{Ref} that corresponds to the current level not to be exceeded in the IGBT.

One limitation of built-in current sensors such as the current mirror output 12 is the dependency of the current ratio with the junction temperature Tj, which can reach sensitivities in the order of 1%/K. In the absence of any counter measure, chip temperature margins should be considered in the product design which decrease the ability to finely detect over-current and measure the correct current value.

Correction circuits are sometimes implemented in such power semiconductor switches or power modules built with such switches. However such correction circuits and temperature sensors add cost and complexity to such power semiconductors and power modules.

### SUMMARY OF INVENTION

This disclosure improves the situation and in particular addresses the problem to find an alternative method to correct the current sensor sensitivity to the junction temperature Tj.

A principle used in the present disclosure is to couple the built-in temperature-dependent current sensor and a temperature sensitive element of the die having a similar temperature curve than the current sensor of the semiconductor switch in order to compensate the temperature dependency of the current sensor and obtain a temperature independent overcurrent detection circuit.

More precisely the present disclosure proposes to provide an Overcurrent detection circuit for a semiconductor switch such as an IGBT or a MOSFET said detection circuit comprising a compensation circuit configured to at least partly compensate a temperature dependency of a built-in current mirror output of said power semiconductor switch, said current mirror output being connected to a measurement resistor Rs, connected between said current mirror output and a low voltage level of a driver voltage source to provide a voltage V_{Rs}=iₛ·Rs, and connected to a first adder input having a second adder input receiving an offset V_{ofst} to provide a mirror voltage Vs=V_{Rs}+V_{ofst} mirroring the current Ic flowing through the power switch emitter-collector or drain-source junction, wherein said compensation circuit comprises a current source configured to provide a reference current i_{R} and connected to a temperature sensitive element of said power semiconductor switch in which said reference current i_{R} flows during at least a dedicated period of measurement through said temperature sensitive element to provide a reference voltage Ve, a comparator, comparing said reference voltage Ve or an amplified reference voltage βVd and said mirror voltage and wherein said compensation circuit is configured to provide at an output of said comparator a detection signal Ocd changing its state when said mirror voltage exceeds said reference voltage Ve or said amplified reference voltage βVd.

The following features may be optionally implemented, separately or in combination one with the others.

The temperature sensitive element being a gate resistor Rg of said semiconductor switch, the current source may be connected to said gate resistance Rg of said power semiconductor switch through an emitter or source of said semiconductor switch, in a way that said reference current i_{R} flows during said at least dedicated period of measurement through said gate resistance Rg to provide said reference voltage Ve, said comparator, comparing said reference voltage Ve and said mirror voltage Vs.

The current source may be configured in parallel with a switch in order to shunt said current source (31) with a command signal line (41) providing a command signal V_{SI} to inhibit flowing of said reference current i_{R} in said gate resistor outside of said dedicated period of measurement, said dedicated period being made of a pulse within a ON period of the semiconductor switch driven by a driver voltage V_{driver}.

The measurement resistor Rs may be connected to the low voltage level of the driver voltage source through a capacitor Cs forming a charging circuit provided to generate the mirror voltage Vs with a trapezoidal voltage shape having a positive voltage ramp lower than the gate voltage Vg, said charging circuit comprising a reset switch connected to said charging circuit to discharge said capacitor Cs and connected to said command signal line.

The temperature sensitive element may be a series of diodes Di located on a die of the semiconductor switch, said current source providing said reference current i_{R} supplying current to said series of diodes Di so that said reference current i_{R} flowing through said series of diodes Di, permanently or during said at least dedicated period of measurement, to provide said reference voltage Vd, amplifying said reference voltage Vd through said amplifier to provide said amplified reference voltage βVd comparing said amplified reference voltage βVd and said mirror voltage in said comparator.

The detection circuit may comprise a logic gate receiving a detection signal Ocd and a measurement inhibition signal line providing an inhibition signal to inhibit false detections outside of said dedicated measurement period, said logic gate providing an overcurrent detection logic signal TI-OCD.

The measurement inhibition signal line may be said command signal line.

The overcurrent detection circuit may be connected to an overcurrent detection input of said command circuit, said command circuit being configured to switch OFF said semiconductor switch upon occurrence of an overcurrent.

The signal line may be issued from a switching controller for the power switch.

### BRIEF DESCRIPTION OF THE DRAWINGS

Other features, details and advantages will be shown in the following detailed description and on the figures, on which:

FIG. 1 is an example of semiconductor power switch with built in current sensor and current measurement circuit;

FIG. 2 is a schematic of a first example of realization of a overcurrent detection circuit according the disclosure;

FIG. 3 is a schematic of a second example of realization of a overcurrent detection circuit according the disclosure;

FIG. 4 is a schematic of a third example of realization of a overcurrent detection circuit according the disclosure;

FIG. 5A is a schematic representation of signals of the first example of realization;

FIG. 5B is a schematic representation of signals of the second example of realization;

FIG. 6 is a resulting curve of the first example of realization.

### DESCRIPTION OF EMBODIMENTS

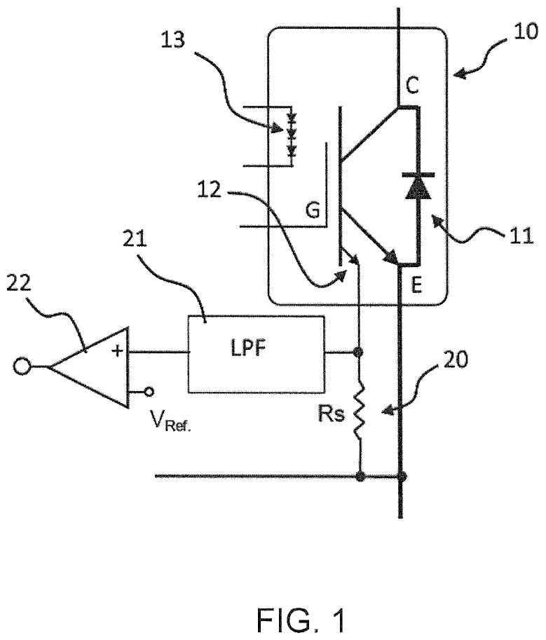

In a power switch such as in FIG. 1 the current sensor output iₛ is a function of the collector current ic and of the junction temperature Tj. For some commercial component, the relation is well expressed by e.g. the following expression:

$${i}_{s} = A \cdot {i}_{c} + B \cdot Tj \cdot {i}_{c} with Vs = Rs \cdot {i}_{s}$$

A and B being two parameter characteristics of the built-in current source for a given sense resistor Rs value. Furthermore, the internal gate resistance of a switch is known to vary e.g. according to:

$$Rg = {R}_{0} + α \cdot Tj$$

with R₀ and α parameter characteristics of the die. Note that these values may be changed by design.

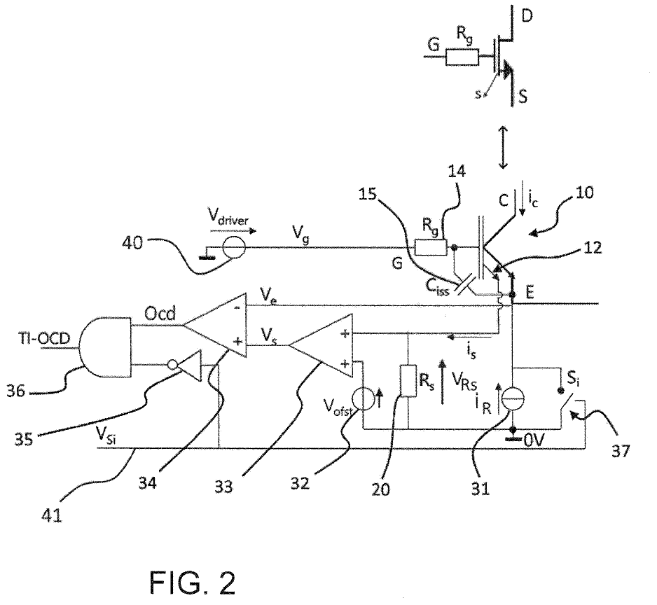

FIG. 2 shows a semiconductor switch 10 such as an IGBT provided with a first example of an overcurrent detection circuit.

In this example is shown that the IGBT may be replaced by a MOSFET shown on top of the figure where the emitter E of the IGBT being replaced by the source of the MOSFET, the collector of the IGBT being replaced by the drain of the MOSFET and the current mirror output being linked to the source of the MOSFET instead of the emitter of the IGBT.

The detection circuit comprises a compensation circuit configured to compensate a temperature dependency of a built-in current mirror of said power semiconductor switch 10, said current mirror output 12 being connected to a measurement resistor Rs 20, connected between said current mirror output and a low voltage level of a driver voltage source 40 to provide a voltage V_{Rs}=iₛ·Rs.

It should be noted that in case of a half-bridge, the schematics of FIG. 2 corresponds to an upper branch switch and in case of a lower branch switch the low voltage level would be the lower voltage of the lower branch switch.

The current mirror output and the resistor are connected together to an adder 33 having a second adder input receiving an offset V_{ofst} 32, to provide a mirror voltage Vs=V_{Rs}+V_{ofst}.

The adder providing a mirror voltage Vs mirroring the current Ic flowing through the power switch collector-emitter or drain-source junction.

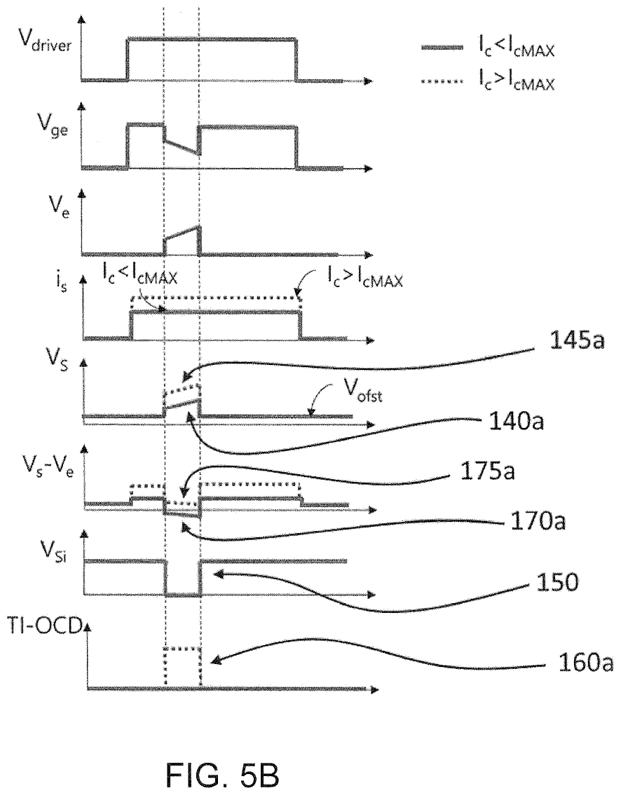

The compensation circuit comprises a current source 31 configured to provide a reference current i_{R}, such current source being connected to a temperature sensitive element, which is in this example the gate resistor Rg 14 of the power semiconductor switch, in which said reference current i_{R} flows during at least a dedicated period of measurement as will be seen in correspondence with FIG. 5A.

The current i_{R}, flowing through the temperature sensitive element 14 in FIG. 2 provides a reference voltage Ve which is input at a comparator 34 having at its other input the voltage Vs in order to compare said reference voltage Ve and said mirror voltage Vs. With this configuration, the compensation circuit is configured to provide at an output of the comparator 34 a detection signal Ocd changing its state when said mirror voltage exceeds said reference voltage Ve.

In this example, the temperature sensitive element being the internal gate resistor Rg 14 of the semiconductor switch, the current source is connected to such gate resistance Rg 14 through the power emitter E or the Kelvin emitter output in case of the IGBT represented on the drawing or the source of the MOSFET switch such as shown above the IGBT on the drawing, in a way that said reference current i_{R} flows through the gate resistance Rg 14 to provide the reference voltage Ve, which is compared at the comparator 34 with said mirror voltage Vs.

The measurement period during which the reference current i_{R} is injected in the gate resistance is defined by the switch 37 in parallel with the current source. When the switch 37 is open it allows the current i_{R} generated by the current generator 31 to flow in the gate resistance. When the switch 37 is closed it shunts the current source 31 and stops the current flowing through the resistance outside the measurement period.

The switch 37 is opened and closed with a command signal line 41 providing a command signal V_{SI} shown in curve 150 in FIG. 5A. Still in FIG. 5A, the dedicated period is made with V_{SI} pulse within a ON period of the semiconductor switch driven by a driver voltage V_{driver} as in curve 100.

The current I_{R} is injected through the gate to emitter of the die. It crosses the internal gate resistor Rg and the input capacitance Ciss. In FIG. 5A, the result causes a drop 110a in the V_{GE} curve 110 and provides the voltage Ve in curve 120 which comprises the voltage drop across Rg subject to I_{R} and which is sent to the comparator 34.

The current sensor output i_{S} is shown in curve 130 in solid line for an emitter collector current of the switch under the overcurrent limit and in curve 135 in dotted line for an emitter-collector current above the overcurrent limit. Such current is crossing the sense resistor Rs to provide a voltage V_{Rs}.

The voltage across Rs is added to the offset voltage V_{ofst}. The result of this addition is the voltage Vs in FIG. 5A, the sensed voltage, which is an image of the sensed current without overcurrent in curve 140 and with overcurrent in curve 145.

The voltages Ve and Vs are compared in the comparator 34 as shown in FIG. 5A as Vs-Ve and If Vs is superior to Ve in the detection period as in curve 175, even for small duration, an over-current is detected. Such over-current corresponds to the square signal TI-OCD 160 in dotted line in correspondence with the detection period Vsi curve 150. In case no overcurrent exist, the curve Vs-Ve in the detection period remains under zero as in curve 170.

The previously described circuit allows to monitor the over-current only at specific moments when a current i_{R} is injected through the gate. Before that instant, when there is no current injected, the value at the output of the comparator is positive. It can easily be discarded by a logical AND gate 36 combination. For instance, an over-current is detected if the output of the comparator is high AND the signal in line 41 that controls the injection is high. Other possibilities of logical gates designs are possible depending on the type of logic available.

Starting from the formulas above it can be said that:

At the very beginning instant of the current injection:

$$Ve = Rg \cdot {i}_{R}$$

Assuming Vs is complemented by an additional offset voltage, we have:

$$Vs - Ve = Rs \cdot A \cdot {i}_{c} + {V}_{ofst} - {R}_{0} \cdot {i}_{R} + Rs \cdot B \cdot Tj \cdot {i}_{c} - α \cdot {T}_{j} \cdot {i}_{R}$$

To obtain a temperature independency of the over-current threshold i_{c}=i_{cMAX}:

$$( Rs \cdot B \cdot Tj \cdot {i}_{c} - α \cdot {T}_{j} \cdot {i}_{R} ) = 0 ⇒ {i}_{R} = \frac{B \cdot Rs \cdot {i}_{cMAX}}{α}$$

To have Vs−Vg=0 when i_{c}=i_{cMAX}:

$${V}_{ofst} = - {i}_{cMAX} \cdot Rs \cdot ( A - \frac{{R}_{0} \cdot B}{α} )$$

Typical values and results are:

| A | 8.0895e−06 | |
|---|---|---|
| B | 1.0195e−07 | |
| Rs | 160 | Ω |
| R₀ | 13 | Ω |
| α | 0.013 | Ω/K |
| i_{cMAX} | 100A | |
| iᵢ | 125.5 | mA |
| V_{ofst} | 1.5018 | V |

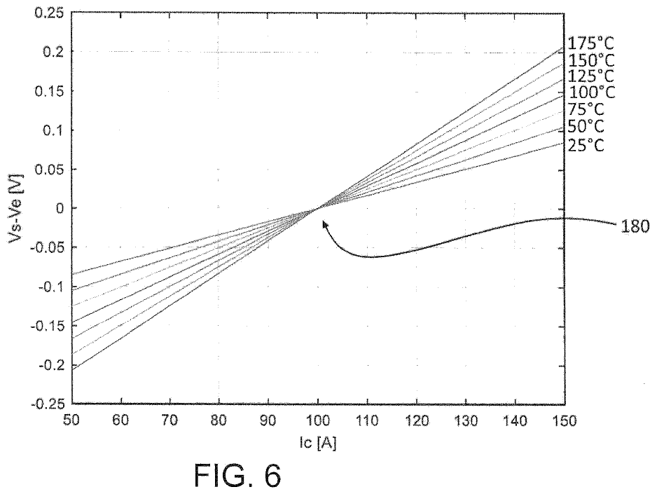

With the above numerical values, the crossing point of Vs and Ve occurs at 100A independently of the junction temperature as shown in FIG. 6 in point 180 on a curve (Vs-Ve) plotted against Ic for different temperatures. In such example, the overcurrent detector is insensitive to the temperature at i_{C}=i_{cMAX}=100 A. The sensitivity of the comparison is >10 mV for 6 A error and increases at high temperature.

As can be seen the compensation obtained by the present disclosure design is very good at a specified current and still correct for currents around such specified current.

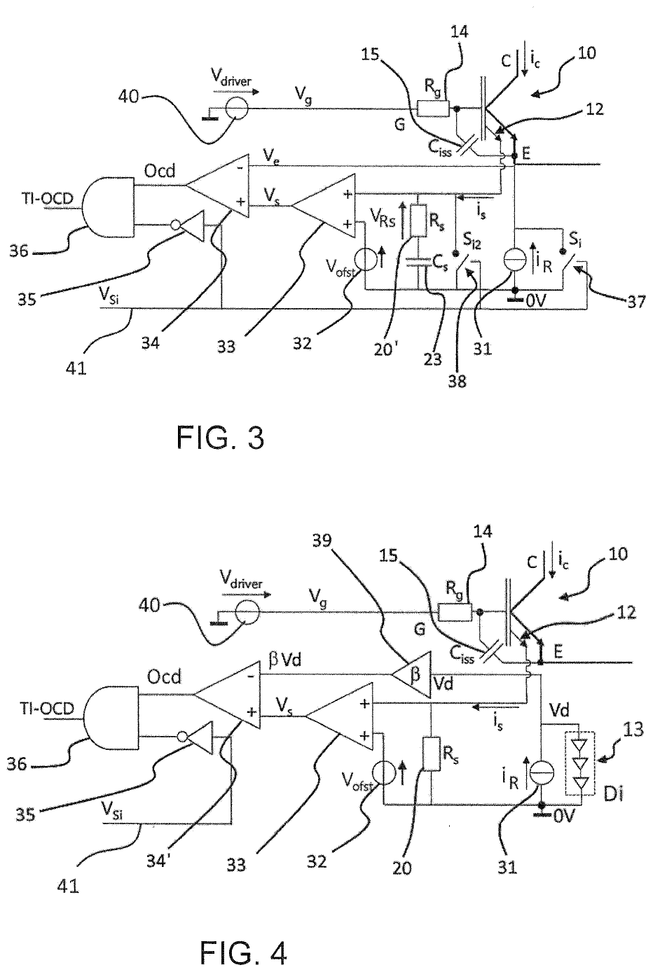

FIG. 3 shows a second example which is based on the example of FIG. 2 but in which a capacitor C_{S} 23 is added between the resistor Rs 20′ and the low voltage level of the circuit to generate a trapezoidal voltage shape V_{S} with a positive voltage ramp but lower than the one of Vg. Thus, in case of over-current, the output of the comparator is high for a longer time. In such case it is necessary to discharge the capacitor Cs and this is done with a further switch 38 which can also be triggered by the V_{SI} signal 41.

The resulting curves are shown in FIG. 5B where it can be seen that Vs in curve 140a without overcurrent and 145a with overcurrent being ramped in the detection period causes a higher Vs-Ve curve 175a when the overcurrent is present causing in turn a longer detection 160a in the detection period Vsi 150.

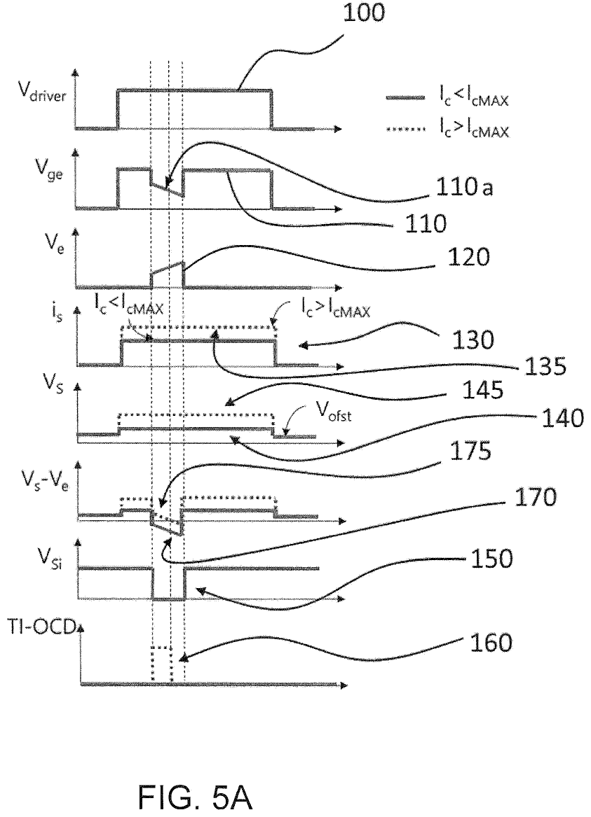

FIG. 4 shows another design where the temperature is estimated from small diodes Di 13 built-in the die of the semiconductor switch as in FIG. 1. When a DC current i_{R} is injected through these diodes, the voltage drop is sensitive to the temperature.

For a constant pre-defined current, the voltage drop across the sensing diode may be expressed as a linear relation with temperature:

$$VT = V 0 - α \cdot Tj$$

Assuming this voltage drop can be scaled by a parameter β, for example with a voltage divider or a multiplier circuit 39 using an operational amplifier, the following relation can be obtained:

$$Vs + VT = Rs \cdot A \cdot ic + Vofst + {V}_{0} \cdot β + Rs \cdot B \cdot Tj \cdot ic - α \cdot Tj \cdot β$$

To obtain a temperature independency of the over-current threshold:

$${i}_{c} = {i}_{cMAX} : ( Rs \cdot B \cdot Tj \cdot ic - α \cdot Tj \cdot β ) = 0 ⇒ β = B \frac{B \cdot Rs \cdot {i}_{cMAX}}{α}$$

in order to have Vs+VT=0 when ic=i_{cMAX}:

$${V}_{ofst} = - {i}_{cMAX} \cdot Rs \cdot ( A + {V}_{0} )$$

In such design, the current source is not connected to the IGBT or MOSFET but to the diodes 13 and the voltage Vd at the pins of the diodes is amplified with amplifier 39 and the result βVd is compared to the output Vs as in the design of FIG. 1.

This design depending on the presence of the diodes Di simplifies the circuit as there is no need to shunt the current source 31.

Concerning the first and second examples, during the injection, the presence of Ciss 15 is responsible for the increase of Ve, and the pull-down of the TI-OCD signal. An over-current is thus detected if the signal TI-OCD becomes high, even for a small moment. A low-cost component may be advantageously used to latch this signal and increase the robustness and detectability of the detection.

In practice, a too small moment may be filtered by the electronic circuit, and it is necessary to define the value of V_{ofst} such that it triggers at the value of the over-current threshold. For this, a calibration method can be used. A current pulse with a value i_{cMAX} can be imposed to the die in on-state. The length of this pulse is generally short (i.e. less than 1s) to prevent any excessive self-heating. The offset voltage V_{ofst} is then increased until the detection of a TI-OCD. The corresponding value of V_{ofst} is defined and applied. The result of this calibration is mostly dependent on the electronic circuit implementation of the TI-OCD. After being performed once, it can be applied to other circuits, even if used with other power modules.

Thus, the identification of the parameter V_{ofst} is practical and low-cost.

The value of i_{R} is less sensitive to the circuit implementation. Prior knowledge of the temperature sensitivity of the built-in current sensor and of the internal gate resistor is required and can be performed easily with conventional measurement set-ups.

It is sometimes required to continuously monitor the over-current. In this case, the temperature-dependent over-current can be measured directly across R_{S} 20, 20′, i.e. without the temperature correction or at the output of the adder 33. If an over-current is detected, a temperature-independent over-current estimation can be instantaneously triggered to verify if the detection is an artefact of the temperature or a real over-current detection.

Thus, both a continuous and a temperature over-current detection can be achieved.

This disclosure is not limited to the examples described here and in example in case other temperature dependent components are present on the semiconductor switch die, such may be used instead of the diodes 13.

1. A semiconductor switch such as an IGBT or a MOSFET equipped with an overcurrent detection circuit said detection circuit comprising a compensation circuit configured to at least partly compensate a temperature dependency of a built-in current mirror-output of said power semiconductor switch, said compensation circuit comprising a measurement resistor Rs connected between a current mirror output of said semiconductor switch and a low voltage level of a driver voltage source to provide a detection voltage V_{Rs}=iₛ·Rs where iₛ is a current output from said current mirror output, said current mirror output being connected further to a first adder input having a second adder input receiving an offset voltage V_{ofst} to provide a mirror voltage Vs=V_{Rs}+V_{ofst}, wherein said compensation circuit comprises a current source configured to provide a reference current i_{R} and connected to a temperature sensitive element of said power semiconductor switch in which said reference current i_{R} flows during at least a dedicated period of measurement through said temperature sensitive element to provide a first reference voltage Ve or a second reference voltage Vd, said compensation circuit comprising further a comparator, comparing said first reference voltage Ve or an amplified second reference voltage βVd and said mirror voltage Vs and wherein said offset voltage V_{ofst} is adapted to said first reference voltage Ve or said second reference voltage Vd of said compensation circuit to provide at an output of said comparator a detection signal Ocd changing its state from an OFF state to an ON state when a current in said semiconductor switch is over a specified level icMAX causing said mirror voltage Vs to exceed said first reference voltage Ve or said amplified second reference voltage βVd, said detection signal Ocd providing said overcurrent detection and wherein said temperature sensitive element being a gate resistor Rg of said semiconductor switch, said current source is connected to said gate resistance Rg of said power semiconductor switch through an emitter or source of said semiconductor switch, in a way that said reference current i_{R} flows during said at least dedicated period of measurement through said gate resistance Rg to provide said first reference voltage Ve, said comparator, comparing said first reference voltage Ve and said mirror voltage Vs.

2. (canceled)

3. The semiconductor switch such as an IGBT or a MOSFET equipped with an overcurrent detection circuit as claimed in claim 1 wherein said current source is configured in parallel with a switch in order to shunt said current source with a command signal line providing a command signal V_{SI} to inhibit flowing of said reference current i_{R} in said gate resistor outside of said dedicated period of measurement, said dedicated period being made of a pulse within a ON period of the semiconductor switch driven by a driver voltage V_{driver}.

4. The semiconductor switch such as an IGBT or a MOSFET equipped with an overcurrent detection circuit as claimed in claim 3 wherein the measurement resistor Rs is connected to the low voltage level of the driver voltage source through a capacitor Cs forming a charging circuit provided to generate the mirror voltage Vs with a trapezoidal voltage shape having a positive voltage ramp lower than the gate voltage Vg, said charging circuit comprising a reset switch connected to said charging circuit to discharge said capacitor Cs and connected to said command signal line.

5. (canceled)

6. The semiconductor switch such as an IGBT or a MOSFET equipped with an_overcurrent detection circuit as claimed in claim 1 comprising a logic gate receiving said detection signal Ocd and a measurement inhibition signal line providing an inhibition signal to inhibit false detections outside of said dedicated measurement period, said logic gate providing an overcurrent detection logic signal TI-OCD.

7. The semiconductor switch such as an IGBT or a MOSFET equipped with an overcurrent detection circuit according to claim 3 comprising a logic gate receiving said detection signal Ocd and a measurement inhibition signal line providing an inhibition signal to inhibit false detections outside of said dedicated measurement period, said logic gate providing an overcurrent detection logic signal TI-OCD, wherein said measurement inhibition signal line is said command signal line.

8. A command circuit for a semiconductor switch comprising an overcurrent detection circuit as claimed in claim 1 wherein said overcurrent detection circuit is connected to an overcurrent detection input of said command circuit, said command circuit being configured to switch OFF said semiconductor switch upon occurrence of an overcurrent.
